(19) United States
(12) Patent Application Publication
(10) Pub. No.: US 2023/0157136 A1
(43) Pub. Date: May 18, 2023

(54) DISPLAY PANEL, DISPLAY DEVICE, AND MANUFACTURING METHOD

(71) Applicant: BOE TECHNOLOGY GROUP CO., LTD., BEIJING (CN)

(72) Inventors: Chunyan XIE, BEIJING (CN); Song ZHANG, BEIJING (CN); Penghao GU, BEIJING (CN); Ziang HAN, BEIJING (CN)

(73) Assignee: BOE TECHNOLOGY GROUP CO., LTD., BEIJING (CN)

(21) Appl. No.: 17/995,383

(22) PCT Filed: Oct. 11, 2021
(86) PCT No.: PCT/CN2021/123048

§ 371 Date: Oct. 3, 2022

(30) Foreign Application Priority Data
Nov. 30, 2020 (CN) 202011372383.7

(51) Int. Cl. H10K 59/80; H10K 59/124; H10K 59/12

(52) U.S. Cl. CPC H10K 59/8731; H10K 59/124; H10K 59/1201; H10K 2102/311

(57) ABSTRACT

The present disclosure provides a display panel, a display device, and a manufacturing method. The display panel includes: a substrate including a display area and a non-display area and having a first groove in the non-display area; a driver circuit layer on a side of the display area of the substrate; a display function layer on a side of the driving circuit layer away from the substrate; an encapsulation layer on a side of the display function layer away from the driver circuit layer, the encapsulation layer including an inorganic encapsulation layer extending to the non-display area, and a part of the inorganic encapsulation layer being in the first groove; and a dam on the non-display area, an orthographic projection of the dam on the substrate being between the first groove and the display area, and the dam being covered by the inorganic encapsulation layer.

### CROSS-REFERENCE TO RELATED APPLICATIONS

The present application is a U.S. National Stage Application under 35 U.S.C. § 371 of International Patent Application No. PCT/CN2021/123048, filed on Oct. 11, 2021, which claims priority to China Patent Application No. 202011372383.7 filed on Nov. 30, 2020, the disclosure of both of which are incorporated by reference herein in entirety.

### TECHNICAL FIELD

The present disclosure relates to a display panel, a display device and a manufacturing method.

### BACKGROUND

With the increasingly diverse applications of a display panel, there are higher and higher appearance and profile requirements of the display panel. Especially for the non-display border area, with the ultimate pursuit of screen ratio, the border area will be further narrowed. An OLED (Organic light Emitting Diode) display device generally uses a thin film encapsulation structure to ensure the water and oxygen barrier property of the OLED devices.

### SUMMARY

According to one aspect of the embodiments of the present disclosure, a display panel is provided. The comprises: a substrate comprising a display area and a non-display area on at least one side of the display area, wherein the substrate has a first groove in the non-display area; a driver circuit layer on a side of the display area of the substrate; a display function layer on a side of the driver circuit layer away from the substrate; an encapsulation layer on a side of the display function layer away from the driver circuit layer, wherein the encapsulation layer comprises an inorganic encapsulation layer, the inorganic encapsulation layer extending to the non-display area, and a portion of the inorganic encapsulation layer being in the first groove; and a dam on the non-display area of the substrate, wherein an orthographic projection of the dam on the substrate is between the first groove and the display area, and the dam is covered by the inorganic encapsulation layer.

In some embodiments, an angle formed between a sidewall of the first groove and an upper surface of the substrate is greater than 90 degrees.

In some embodiments, a width of an opening of the first groove is greater than a width of a bottom of the first groove.

In some embodiments, the substrate comprises: a first substrate, a first buffer layer on the first substrate, a second substrate on a side of the first buffer layer away from the first substrate, and a second buffer layer on a side of the second substrate away from the first buffer layer, wherein the first groove is at least disposed on the second substrate.

In some embodiments, a bottom of the first groove exposes a portion of the first buffer layer, and the portion of the inorganic encapsulation layer in the first groove is in contact with the portion of the first buffer layer.

In some embodiments, a width of an opening of the first groove in a direction perpendicular to an extension direction of the first groove is 10 microns to 100 microns.

In some embodiments, the substrate comprises a plurality of first grooves, wherein the plurality of first grooves are substantially arranged along an extension direction of an edge of the substrate, and any two of the plurality of first grooves are not connected with each other.

In some embodiments, the first groove extends substantially along an extension direction of an edge of the substrate.

In some embodiments, the dam comprises a first dam and a second dam on a side of the first dam away from the display area, wherein an orthographic projection of the second dam on the substrate is between an orthographic projection of the first dam on the substrate and the first groove.

In some embodiments, the inorganic encapsulation layer comprises a first inorganic encapsulation layer on a side of the display function layer away from the driver circuit layer and a second inorganic encapsulation layer on a side of the first inorganic encapsulation layer away from the display function layer; and the encapsulation layer further comprises an organic encapsulation layer between the first inorganic encapsulation layer and the second inorganic encapsulation layer.

In some embodiments, the non-display area comprises: a first non-display area, a second non-display area, a third non-display area and a fourth non-display area all around the display area, wherein the first non-display area is adjacent to the second non-display area, the third non-display area is opposite to the first non-display area, and the fourth non-display area is opposite to the second non-display area; a first corner area is arranged between the first non-display area and the second non-display area, a second corner area is arranged between the second non-display area and the third non-display area, a third corner area is arranged between the third non-display area and the fourth non-display area, and a fourth corner area is arranged between the first non-display area and the fourth non-display area; and the first groove is in at least one of the first corner area, the second corner area, the third corner area or the fourth corner area, or at least one of the first non-display area, the second non-display area, the third non-display area or the fourth non-display area.

In some embodiments, the display area comprises a stretchable display area, the first corner area, the second corner area, the third corner area and the fourth corner area being arranged on a side of the stretchable display area.

In some embodiments, the substrate further has a second groove on a side of the first groove away from the dam, wherein an angle formed between a sidewall of the second groove and an upper surface of the substrate is less than 90 degrees, and another portion of the inorganic encapsulation layer is in the second groove.

In some embodiments, the substrate further has a second groove on a side of the first groove away from the dam, wherein an angle formed between a sidewall of the second groove and a bottom of the second groove is less than 90 degrees, and another portion of the inorganic encapsulation layer is in the second groove.

In some embodiments, a width of an opening of the second groove is less than a width of a bottom of the second groove.

In some embodiments, the another portion of the inorganic encapsulation layer in the second groove forms a slit at a bottom corner of the second groove.

In some embodiments, the second groove extends substantially along an extension direction of an edge of the substrate.

In some embodiments, a depth of the second groove is approximately equal to a depth of the first groove.

According to another aspect of embodiments of the present disclosure, a display device is provided. The display device comprises the display panel as described above.

According to another aspect of embodiments of the present disclosure, a manufacturing method of a display panel is provided. The manufacturing method comprises: providing a substrate comprising a display area and a non-display area on at least one side of the display area; forming a driver circuit layer on a side of the display area of the substrate; forming a dam on the non-display area of the substrate; forming a display function layer on a side of the driver circuit layer away from the substrate; etching the non-display area of the substrate to form a first groove in the non-display area, the first groove being on a side of the dam away from the display area; and forming an encapsulation layer on a side of the display function layer away from the driver circuit layer, wherein the encapsulation layer comprises an inorganic encapsulation layer, the inorganic encapsulation layer extending to the non-display area and covering the dam, and a portion of the inorganic encapsulation layer being in the first groove.

In some embodiments, the providing of the substrate comprises: providing a first substrate; forming a first buffer layer on the first substrate; forming a second substrate on a side of the first buffer layer away from the first substrate; and forming a second buffer layer on a side of the second substrate away from the first buffer layer; and the etching of the non-display area of the substrate comprises: etching the second buffer layer and the second substrate to form the first groove exposing a portion of the first buffer layer; wherein the portion of the inorganic encapsulation layer in the first groove is in contact with the portion of the first buffer layer in the forming of the encapsulation layer.

In some embodiments, the etching of the non-display area of the substrate further comprises: etching the second buffer layer and the second substrate to form a second groove exposing another portion of the first buffer layer, the second groove being on a side of the first groove away from the dam; wherein another portion of the inorganic encapsulation layer is in the second groove and is in contact with the another portion of the first buffer layer in the forming of the encapsulation layer.

Other features and advantages of the present disclosure will become apparent from the following detailed description of exemplary embodiments of the present disclosure in conjunction with the accompanying drawings.

### BRIEF DESCRIPTION OF THE DRAWINGS

The accompanying drawings which constitute part of this specification, illustrate the exemplary embodiments of the present disclosure, and together with this specification, serve to explain the principles of the present disclosure.

The present disclosure may be more explicitly understood from the following detailed description with reference to the accompanying drawings, in which:

FIG. 1 is a top view showing a display panel according to an embodiment of the present disclosure;

FIG. 2 is an enlarged schematic diagram showing a portion of the display panel at a circle 101 in FIG. 1 according to an embodiment of the present disclosure;

FIG. 3 is a schematic cross-sectional view showing a structure of the display panel taken along a line A-A′ in FIG. 2 according to an embodiment of the present disclosure;

FIG. 4 is an enlarged schematic diagram showing a portion of the display panel at a circle 101 in FIG. 1 according to another embodiment of the present disclosure;

FIG. 5 is a schematic cross-sectional view showing a structure of the display panel taken along a line B-B′ in FIG. 4 according to another embodiment of the present disclosure;

FIG. 6 is a flowchart showing a manufacturing method of a display panel according to an embodiment of the present disclosure;

FIG. 7 is a schematic cross-sectional view showing a structure at a stage in a manufacturing process of a display panel according to an embodiment of the present disclosure;

FIG. 8 is a schematic cross-sectional view showing a structure at another stage in a manufacturing process of a display panel according to an embodiment of the present disclosure;

FIG. 9 is a schematic cross-sectional view showing a structure at another stage in a manufacturing process of a display panel according to an embodiment of the present disclosure;

FIG. 10 is a schematic cross-sectional view showing a structure at another stage in a manufacturing process of a display panel according to an embodiment of the present disclosure;

FIG. 11 is a schematic cross-sectional view showing a structure at another stage in a manufacturing process of a display panel according to an embodiment of the present disclosure;

FIG. 12 is a schematic cross-sectional view showing a first groove of a display panel according to an embodiment of the present disclosure.

It should be understood that the dimensions of the various parts shown in the accompanying drawings are not drawn according to the actual scale. In addition, the same or similar reference signs are used to denote the same or similar components.

### DETAILED DESCRIPTION

Various exemplary embodiments of the present disclosure will now be described in detail in conjunction with the accompanying drawings. The description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity or importance, but are merely used to distinguish between different parts. A word such as “comprise”, “include”, or the like means that the element before the word covers the element(s) listed after the word without excluding the possibility of also covering other elements. The terms “up”, “down”, “left”, “right”, or the like are used only to represent a relative positional relationship, and the relative positional relationship may be changed correspondingly if the absolute position of the described object changes.

In the present disclosure, when it is described that a particular device is located between the first device and the second device, there may be an intermediate device between the particular device and the first device or the second device, and alternatively, there may be no intermediate device. When it is described that a particular device is connected to other devices, the particular device may be directly connected to said other devices without an intermediate device, and alternatively, may not be directly connected to said other devices but with an intermediate device.

All the terms (comprising technical and scientific terms) used in the present disclosure have the same meanings as understood by those skilled in the art of the present disclosure unless otherwise defined. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The inventors of the present disclosure have found that the thin-film encapsulation structure is generally an inorganic/organic laminated structure. In an edge area of an OLED device, a certain length of the inorganic encapsulation layer must be provided to ensure the encapsulation characteristic of the device (that is, the water and oxygen barrier property of the OLED device) as much as possible, which however is not conducive to the narrowing of the border of the display device.

In view of this, embodiments of the present disclosure provide a display panel to improve the water and oxygen barrier property of the OLED device for a display device with a narrow border, that is, to improve the encapsulation characteristic of the OLED device, thereby facilitating the narrowing of the border of the display device.

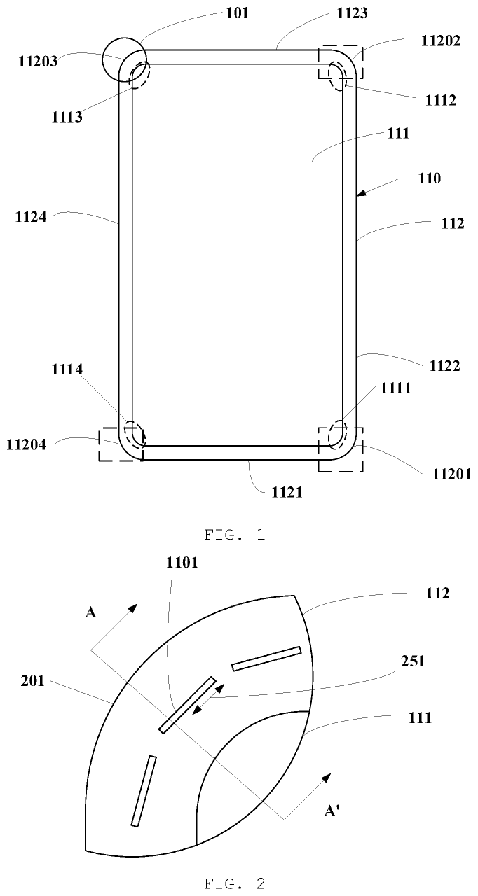

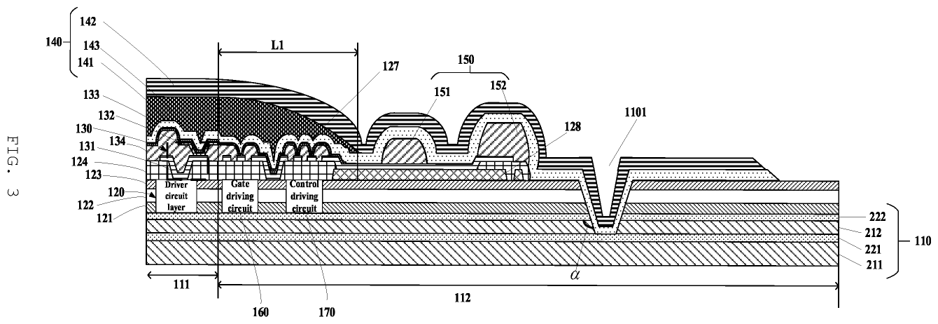

FIG. 1 is a top view showing a display panel according to an embodiment of the present disclosure. FIG. 2 is an enlarged schematic diagram showing a portion of the display panel at a circle 101 in FIG. 1 according to an embodiment of the present disclosure. FIG. 3 is a schematic cross-sectional view showing a structure of the display panel taken along a line A-A′ in FIG. 2 according to an embodiment of the present disclosure. The display panel according to some embodiments of the present disclosure will be described in detail below with reference to FIGS. 1 to 3.

As shown in FIGS. 1 and 2, the display panel comprises a substrate 110. The substrate 110 comprises a display area 111 and a non-display area 112 on at least one side of the display area 111. For example, the non-display area 112 is around the display area 111. The substrate 110 has a first groove 1101 in the non-display area. For example, the first groove 1101 is between a cutting line 201 and the display area 111.

As shown in FIG. 3, the display panel further comprises a driver circuit layer 120 on a side of the display area 111 of the substrate.

For example, as shown in FIG. 3, the driver circuit layer 120 comprises a first insulating layer 121 on the substrate 110, a second insulating layer 122 on a side of the first insulating layer 121 away from the substrate 110, an interlayer dielectric layer 123 on a side of the second insulating layer 122 away from the substrate 110, an active layer and a conductive layer (not shown) for forming a thin film transistor, etc. For example, materials of the first insulating layer 121, the second insulating layer 122, and the interlayer dielectric layer 123 comprise silicon dioxide, silicon nitride, or the like.

Here, known structures can be adopted for the active layer, the conductive layer, and the like in the driver circuit layer. For example, the active layer may be located on the substrate 110. The active layer may comprise a semiconductor layer. The active layer can be covered by the first insulating layer 121. The conductive layer may comprise a gate electrode, a source electrode, and a drain electrode. For example, the gate electrode is located on the first insulating layer 121. The gate electrode is covered by the second insulating layer 122. The source electrode and the drain electrode are spaced apart from each other, and are on a side of the interlayer dielectric layer 123 away from the substrate. The source electrode can be electrically connected to the active layer through a conductive via passing through the first insulating layer 121, the second insulating layer 122 and the interlayer dielectric layer 123, and the drain electrode can be electrically connected to the active layer through another conductive via passing through the first insulating layer 121, the second insulating layer 122 and the interlayer dielectric layer 123. Of course, those skilled in the art can understand that the driver circuit layer may further comprise other known structural layers, which will not be described in detail here.

As shown in FIG. 3, the display panel further comprises a display function layer 130 on a side of the driver circuit layer 120 away from the substrate 110. For example, as shown in FIG. 3, the display function layer 130 comprises a first electrode layer (e.g., an anode layer) 131 on the driver circuit layer 120, a light emitting layer 132 on a side of the first electrode layer 131 away from the substrate, and a second electrode layer (e.g., a cathode layer) 133 on a side of the light emitting layer 132 away from the substrate. The first electrode layer 131 may be electrically connected to the source electrode or the drain electrode. The light emitting layer 132 is electrically connected to the first electrode layer 131 and the second electrode layer 133, respectively. For example, a material of the first electrode layer 131 comprises a conductive material such as ITO (Indium Tin Oxide), silver (Ag), or the like. For example, the first electrode layer may adopt a structure of ITO/Ag/ITO. For example, a material of the second electrode layer 133 comprises a conductive material such as metal (e.g., magnesium, silver or an alloy thereof, etc.), or the like. Of course, those skilled in the art can understand that the display function layer 130 may further comprise another structural layer, such as an electron transport layer, a hole transport layer, an electron blocking layer and a hole blocking layer, etc. These structural layers may adopt known structures, which will not be described in detail here.

As shown in FIG. 3, the display panel further comprises an encapsulation layer 140 on a side of the display function layer 130 away from the driver circuit layer 120. The encapsulation layer 140 comprises an inorganic encapsulation layer. The inorganic encapsulation layer extends to the non-display area 112 and a portion of the inorganic encapsulation layer is in the first groove 1101. For example, as shown in FIG. 3, the inorganic encapsulation layer 140 comprises a first inorganic encapsulation layer 141 on a side of the display function layer 130 away from the driver circuit layer 120 and a second inorganic encapsulation layer 142 on a side of the first inorganic encapsulation layer 141 away from the display function layer 130. For example, materials of the first inorganic encapsulation layer 141 and the second inorganic encapsulation layer 142 comprise silicon nitride, silicon oxynitride, or the like. A portion of the first inorganic encapsulation layer 141 and a portion of the second inorganic encapsulation layer 142 are in the first groove 1101.

In some embodiments, as shown in FIG. 3, the encapsulation layer 140 further comprises an organic encapsulation layer 143. The organic encapsulation layer 143 is between the first inorganic encapsulation layer 141 and the second inorganic encapsulation layer 142. For example, a material of the organic encapsulation layer 143 comprises PMMA (poly (methyl methacrylate), also known as acrylic) or the like. In addition, FIG. 3 shows that a portion of the organic encapsulation layer 143 on the non-display area 112 has a length L1. The length L1 can be specified according to actual needs. For example, the organic encapsulation layer 143 does not cross a dam (as described below).

As shown in FIG. 3, the display panel further comprises a dam 150 on the non-display area 112 of the substrate 110. An orthographic projection of the dam 150 on the substrate 110 is between the first groove 1101 and the display area 111. The dam 150 is covered by the inorganic encapsulation layer. For example, the dam 150 is covered by the first inorganic encapsulation layer 141 and the second inorganic encapsulation layer 142. For example, as shown in FIG. 3, the dam 150 may comprise a first dam 151 and a second dam 152 on a side of the first dam 151 away from the display area 111. An orthographic projection of the second dam 152 on the substrate 110 is between an orthographic projection of the first dam 151 on the substrate 110 and the first groove 1101. That is, the first groove 1101 is on a side of the second dam 152 away from the first dam 151.

In some embodiments, as shown in FIG. 3, the display panel may further comprise a pixel defining layer 134 between the encapsulation layer and the driver circuit layer. The pixel defining layer 134 is formed with an opening in which the light emitting layer 132 is located. In some embodiments, a material of the pixel defining layer 134 is the same as a material of the dam 150. For example, in the process of forming the pixel defining layer 134, the dam 150 can be formed simultaneously in the same patterning process.

Heretofore, a display panel according to some embodiments of the present disclosure is provided. The display panel comprises: a substrate comprising a display area and a non-display area on at least one side of the display area, wherein the substrate has a first groove in the non-display area; a driver circuit layer on a side of the display area of the substrate; a display function layer on a side of the driver circuit layer away from the substrate; an encapsulation layer on a side of the display function layer away from the driver circuit layer, wherein the encapsulation layer comprises an inorganic encapsulation layer, the inorganic encapsulation layer extending to the non-display area and a portion of the inorganic encapsulation layer being in the first groove; and a dam on the non-display area of the substrate, wherein an orthographic projection of the dam on the substrate is between the first groove and the display area, and the dam is covered by the inorganic encapsulation layer. In the display panel, since a portion of the inorganic encapsulation layer is located in the first groove, the length of the inorganic encapsulation layer can be extended, so that the water and oxygen barrier property of the display panel can be improved for the display device with a narrow border. That is, the encapsulation characteristic of the display panel can be improved, thereby facilitating the narrowing of the border of the display device.

In other words, in a limited border area, the encapsulation layer can be extended due to the first groove described above, so the width of the border can be reduced, and the width of the display area can be increased, thereby increasing the screen ratio of the display panel.

In some embodiments, as shown in FIG. 1, the non-display area 112 comprises: a first non-display area 1121, a second non-display area 1122, a third non-display area 1123 and a fourth non-display area 1124 all around the display area 111. The first non-display area 1121 is adjacent to the second non-display area 1122, the third non-display area 1123 is opposite to the first non-display area 1121, and the fourth non-display area 1124 is opposite to the second non-display area 1122. A first corner area 11201 is arranged between the first non-display area 1121 and the second non-display area 1122, a second corner area 11202 is arranged between the second non-display area 1122 and the third non-display area 1123, a third corner area 11203 is arranged between the third non-display area 1123 and the fourth non-display area 1124, and a fourth corner area 11204 is arranged between the first non-display area 1121 and the fourth non-display area 1124. The first groove 1101 is in at least one of the first corner area 11201, the second corner area 11202, the third corner area 11203 or the fourth corner area 11204. The four corner areas can have stretchable structures. Designing the first groove on the peripheral border of the stretchable structure can ensure the encapsulation effect of the stretchable area as much as possible, and at the same time, maximize the display area and minimize the non-display area as much as possible.

In other embodiments, the first groove 1101 is in at least one of the first non-display area 1121, the second non-display area 1122, the third non-display area 1123 or the fourth non-display area 1124. This can facilitate the narrowing of the border of the display device.

In some embodiments, the display layer 111 comprises a stretchable display area. The first corner area 11201, the second corner area 11202, the third corner area 11203 and the fourth corner area 11204 is on a side of the stretchable display area. For example, as shown in FIG. 2, the stretchable display area comprises a first stretchable display area 1111, a second stretchable display area 1112, a third stretchable display area 1113 and a fourth stretchable display area 1114. The first corner area 11201 is on a side (e.g., outside) of the first stretchable display area 1111, the second corner area 11202 is on a side (e.g., outside) of the second stretchable display area 1112, the third corner area 11203 is on a side (e.g., outside) of the third stretchable display area 1113, and the fourth corner area 11204 is on a side (e.g., outside) of the fourth stretchable display area 1114.

The number of the first grooves can be set according to the requirement of the border, for example, it can be set to be greater than or equal to one. In some embodiments, as shown in FIG. 2, the substrate 110 may comprise a plurality of first grooves 1101. The plurality of first grooves 1101 are substantially arranged along an extension direction of an edge of the substrate. Any two of the plurality of first grooves 1101 are not connected with each other. That is, the first grooves may be a discontinuous structure, which is beneficial to improve the stability of the structure of the first groove. Of course, those skilled in the art can understand that the first groove can also be a continuous structure. Therefore, the scope of the present disclosure is not limited thereto.

In some embodiments, as shown in FIG. 2, the first groove 1101 extends substantially along an extension direction of an edge of the substrate.

In some embodiments, as shown in FIG. 3, an angle α formed between a sidewall of the first groove 1101 and an upper surface of the substrate 110 (e.g., an upper surface of the second substrate 212) is greater than 90 degrees. That is, the angle α is an obtuse angle. As shown in FIG. 3, a width of an opening of the first groove 1101 is greater than a width of a bottom of the first groove 1101. In this way, in the process of forming the inorganic encapsulation layer, the portion of the inorganic encapsulation layer located in the first groove can be grown more uniformly and densely, which is beneficial to improve the water and oxygen barrier property of the display panel.

In some embodiments, as shown in FIG. 2, a width of an opening of the first groove 1101 in a direction perpendicular to an extension direction 251 of the first groove is 10 microns to 100 microns. For example, the width of the opening of the first groove 1101 is 10 microns to 30 microns. In some embodiments, a depth of the first groove 1101 ranges from 5 microns to 20 microns.

In some embodiments, as shown in FIG. 3, the substrate 110 comprises: a first substrate 211, a first buffer layer 221 on the first substrate 211, a second substrate 212 on a side of the first buffer layer 221 away from the first substrate 211, and a second buffer layer 222 on a side of the second substrate 212 away from the first buffer layer 221. For example, the first substrate 211 and the second substrate 212 each is a PI (Polyimide) substrate. The first groove 1101 is at least disposed on the second substrate. For example, in a case that the first groove 1101 does not penetrate through the second substrate 212 (i.e., a depth of the first groove is less than a thickness of the second substrate), the first groove is provided on the second substrate.

In some embodiments, a bottom of the first groove 101 exposes a portion of the first buffer layer 221, and the portion of the inorganic encapsulation layer (e.g., the first inorganic encapsulation layer 141 or the second inorganic encapsulation layer 142) in the first groove 1101 is in contact with the portion of the first buffer layer 221. That is, the depth of the first groove 1101 may be equal to the thickness of the second substrate 212. The first groove penetrates through the second substrate. In the embodiment, the inorganic encapsulation layer is in direct contact with the first buffer layer 221 (for example, a material of the first buffer layer is an inorganic insulating material), which can increase the adhesion at the interface therebetween and further improve the water and oxygen barrier property of the display panel.

Certainly, it can be understood by those skilled in the art that the structure of the substrate 110 described above is only exemplary, and the scope of the present disclosure is not limited thereto. For example, the substrate 110 may comprise a single substrate layer and a buffer layer on the single substrate layer. The first groove 1101 is in the single substrate layer.

In some embodiments, as shown in FIG. 3, the display panel further comprises a planarization layer 124 on a side of the driver circuit layer 120 away from the substrate 110. For example, the planarization layer 124 comprises an organic material. The planarization layer 124 covers the interlayer dielectric layer 123. The planarization layer 124 has a through hole exposing the driver circuit layer 120, and the first electrode layer 131 is electrically connected to the driver circuit layer 120 through the through hole. For example, the planarization layer 124 has a through hole exposing the source electrode or the drain electrode (not shown in FIG. 3) of the thin film transistor of the driver circuit layer 120, and the first electrode layer 131 is electrically connected to the source electrode or the drain electrode through the through hole.

In some embodiments, as shown in FIG. 3, the display panel further comprises a first conductive layer 127 on a side of the interlayer dielectric layer 123 away from the substrate 110. The first conductive layer 127 is in the non-display area 112. The first conductive layer 127 is isolated from the first electrode layer 131. The first conductive layer 127 is in contact with the second electrode layer 133. For example, a material of the first conductive layer 127 is the same as a material of the first electrode layer 131. For example, the first conductive layer 127 and the first electrode layer 131 can be formed in the same patterning process.

In some embodiments, as shown in FIG. 3, the display panel further comprises a second conductive layer 128 on a side of the interlayer dielectric layer 123 away from the substrate 110. The second conductive layer 128 is in the non-display area 112. The second conductive layer 128 is in contact with a portion of the first conductive layer 127. For example, a material of the second conductive layer 128 comprises metal.

In some embodiments, as shown in FIG. 3, the display panel further comprises a gate driving circuit 160 and a control driving circuit 170 located on the non-display area 112. The gate driving circuit 160 and the control driving circuit 170 are formed in the first insulating layer 121, the second insulating layer 122 and the interlayer dielectric layer 123. The gate driving circuit 160 and the control driving circuit 170 adopt known circuit structures, which will not be described in detail here.

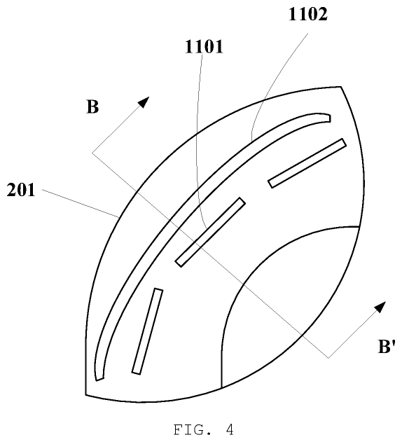

FIG. 4 is an enlarged schematic diagram showing a portion of the display panel at a circle 101 in FIG. 1 according to another embodiment of the present disclosure. FIG. 5 is a schematic cross-sectional view showing a structure of the display panel taken along a line B-B′ in FIG. 4 according to another embodiment of the present disclosure. Here, some structures of the display panel in FIG. 5 that are similar to those shown in FIG. 3 will not be described herein.

In some embodiments, as shown in FIGS. 4 and 5, the substrate 110 further has a second groove 1102 on a side of the first groove 1101 away from the dam 150. That is, an orthographic projection of the first groove 1101 on the substrate 110 is between an orthographic projection of the dam 150 on the substrate and an orthographic projection of the second groove 1102 on the substrate 110. An angle β formed between a sidewall of the second groove 1102 and an upper surface of the substrate 110 (e.g., an upper surface of the second substrate 212) is less than 90 degrees. That is, the angle β is an acute angle. A width of an opening of the second groove 1102 is less than a width of a bottom of the second groove 1102. Another portion of the inorganic encapsulation layer (e.g., the first inorganic encapsulation layer 141 and the second inorganic encapsulation layer 142) is in the second groove 1102. For example, the another portion of the inorganic encapsulation layer in the second groove 1102 forms a slit (not shown in the figure) at a bottom corner of the second groove 1102.

In some embodiments, as shown in FIG. 5, an angle θ formed between a sidewall of the second groove 1102 and a bottom of the second groove 1102 is less than 90 degrees. That is, the angle θ is an acute angle.

In the above structure, the second groove is recessed into the substrate to form an inverted groove. In this way, during the growth of the inorganic encapsulation layer on the structure, it is difficult for the airflow to reach the narrow area at the bottom corner of the second groove. Therefore, in the area of the bottom corner of the second groove, the inorganic encapsulation layer will become thinner, and may form a sharp-corner slit at the bottom corner. Such a structure can serve as a crack stop structure. For example, if a crack extends to the point, it will break at the bottom corner and cannot extend further, which can cut off the tendency of water and oxygen intrusion. Furthermore, with the stop structure, an opening of a mask used in a chemical vapor deposition process for forming the inorganic encapsulation layer can be set outside the cutting line 201 to ensure the thickness uniformity of the film layer in the entire encapsulation area, which can further improve the encapsulation performance.

In some embodiments, as shown in FIG. 5, the bottom of the second groove 1102 exposes another portion of the first buffer layer 221, and the portion of the inorganic encapsulation layer (e.g., the first inorganic encapsulation layer 141 or the second inorganic encapsulation layer 142) in the second groove 1102 is in contact with the another portion of the first buffer layer 221. In the embodiment, the inorganic encapsulation layer is in direct contact with the first buffer layer 221 (for example, a material of the first buffer layer is an inorganic insulating material), which can increase the adhesion at the interface therebetween, and thereby improve the water and oxygen barrier property of the display panel to a certain extent.

In some embodiments, a depth of the second groove 1102 ranges from 5 microns to 20 microns. For example, the depth of the second groove 1102 is approximately equal to the depth of the first groove 1101.

In some embodiments, the second groove 1102 may be a continuous structure (as shown in FIG. 4), or may be a discontinuous structure.

In some embodiments, as shown in FIG. 4, the second groove 1102 extends substantially along an extension direction of an edge of the substrate.

In some embodiments, the second groove 1102 is in at least one of the first corner area 11201, the second corner area 11202, the third corner area 11203, or the fourth corner area 11204, or at least one of the first non-display area 1121, the second non-display area 1122, the third non-display area 1123 or the fourth non-display area 1124.

In some embodiments of the present disclosure, in the border area of the display panel, the organic encapsulation layer generally does not exceed the dam structure, and the inorganic encapsulation layer may exceed the dam structure to ensure the water and oxygen barrier property of the encapsulation layer. The longer the extension length of the inorganic encapsulation layer is, the stronger the water and oxygen barrier property of the encapsulation layer is. A first groove structure is arranged on a flexible substrate with the segment structure, and the inorganic encapsulation layer grows along the first groove structure, which can extend the extension length of the inorganic encapsulation layer, and in conjunction with the inverted second groove, can prevent cracks from growing along the inorganic encapsulation layer, that is, can break the growth path of cracks, and thereby further improving the encapsulation characteristic. The above structure can reduce the width of the border and increase the size of the display area, thereby increasing the screen ratio.

In some embodiments of the present disclosure, a display device is further provided. The display device comprises the display panel as described above. For example, the display device may be any product or component having a display function, such as a display panel, a mobile phone, a tablet computer, a television, a display, a notebook computer, a digital photo frame, a navigator, or the like.

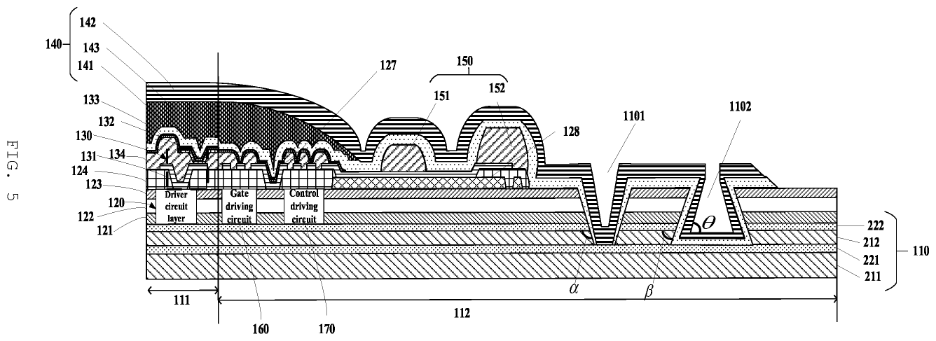

FIG. 6 is a flowchart showing a manufacturing method of a display panel according to an embodiment of the present disclosure. As shown in FIG. 6, the manufacturing method comprises steps S602 to S612.

In step S602, a substrate is provided, wherein the substrate comprises a display area and a non-display area on at least one side of the display area.

In step S604, a driver circuit layer is formed on a side of the display area of the substrate.

In step S606, a dam is formed on the non-display area of the substrate.

In step S608, a display function layer is formed on a side of the driver circuit layer away from the substrate.

In step S610, the non-display area of the substrate is etched to form a first groove in the non-display area, the first groove being on a side of the dam away from the display area. In other words, an orthographic projection of the dam on the substrate is between the first groove and the display area.

In step S612, an encapsulation layer is formed on a side of the display function layer away from the driver circuit layer, wherein the encapsulation layer comprises an inorganic encapsulation layer, the inorganic encapsulation layer extending to the non-display area and covering the dam, and a portion of the inorganic encapsulation layer being in the first groove.

Heretofore, a manufacturing method of a display panel according to some embodiments of the present disclosure is provided. In the manufacturing method, the first groove is formed in the non-display area of the substrate, and during the process of forming the encapsulation layer, the inorganic encapsulation layer of the encapsulation layer extends to the non-display area, and a portion of the inorganic encapsulation layer is in the first groove. In this way, in the case of a display device having a narrow border, the water and oxygen barrier property of the display panel can be improved, that is, the encapsulation characteristic of the display panel can be improved.

FIGS. 7 to 11 and FIG. 5 are schematic cross-sectional views showing structures at several stages of a manufacturing process of a display panel according to some embodiments of the present disclosure. The manufacturing method of the display panel according to some embodiments of the present disclosure will be described in detail with reference to FIGS. 7 to 11 and FIG. 5.

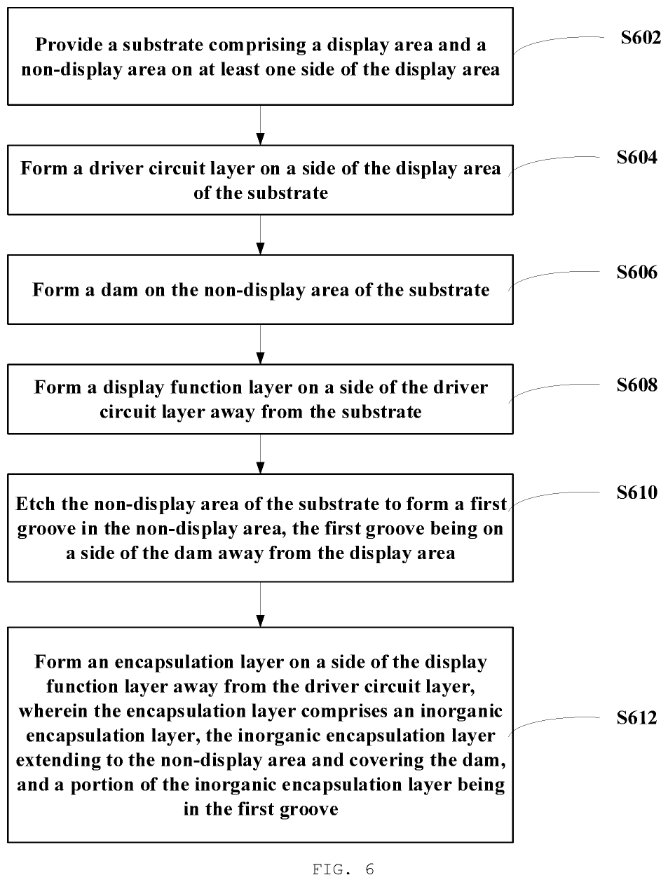

First, as shown in FIG. 7, a substrate 110 is provided, wherein the substrate 110 comprises a display area 111 and a non-display area 112 on at least one side of the display area 111. For example, the step of providing the substrate comprises: providing a first substrate 211; forming a first buffer layer 221 on the first substrate 211; forming a second substrate 212 on a side of the first buffer layer 221 away from the first substrate 211; and forming a second buffer layer 222 on a side of the second substrate 212 away from the first buffer layer 221.

Next, as shown in FIG. 8, a driver circuit layer 120 is formed on a side of the display area 111 of the substrate 110. For example, in the process of forming the driver circuit layer 120, a first insulating layer 121 on the substrate 110, a second insulating layer 122 on a side of the first insulating layer 121 away from the substrate 110, an interlayer dielectric layer 123 on a side of the second insulating layer 122 away from the substrate 110, an active layer and a conductive layer for forming a thin film transistor (not shown) can be formed by processes such as deposition and patterning.

In some embodiments, as shown in FIG. 8, in the process of forming the driver circuit layer 120, a gate driving circuit 160 and a control driving circuit 170 may also be formed.

In some embodiments, as shown in FIG. 8, a second conductive layer 128 on a side of the interlayer dielectric layer 123 away from the substrate 110 and a planarization layer 124 on a side of the driver circuit layer 120 away from the substrate 110 may also be formed.

the above processes of forming the driver circuit layer 120, the gate driving circuit 160, the control driving circuit 170, the second conductive layer 128 and the planarization layer 124 can adopt known techniques, which will not be described in detail here.

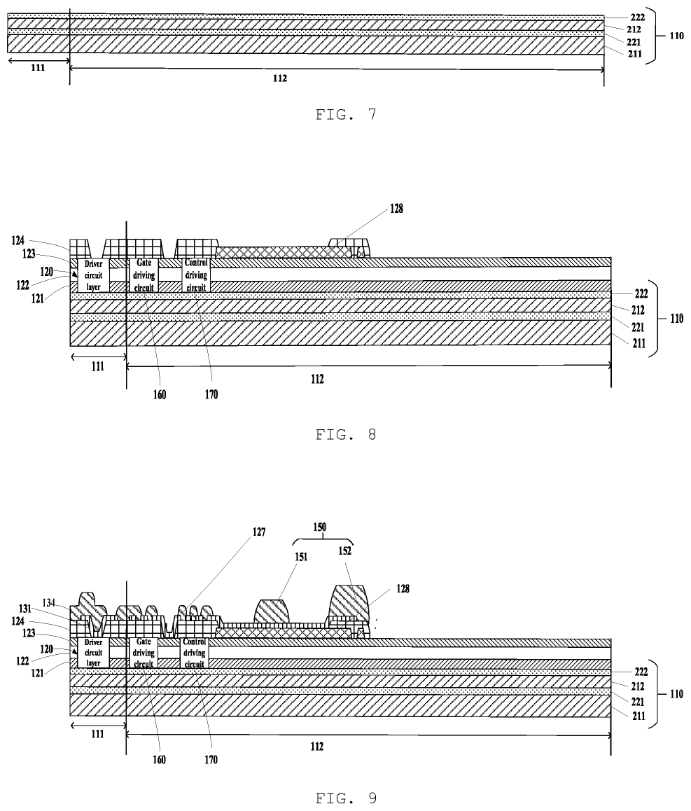

Next, as shown in FIG. 9, a dam 150 is formed on the non-display area 112 of the substrate 110. For example, a first electrode layer 131 on the driver circuit layer 120 and a first conductive layer 127 on a side of the interlayer dielectric layer 123 away from the substrate 110 can be formed through deposition and patterning processes. The first conductive layer 127 is located on the non-display area. Then, a pixel defining layer 134 on a side of the planarization layer 124 away from the substrate and a dam 150 on the non-display area are formed through deposition and patterning processes. For example, the dam 150 may comprise a first dam 151 and a second dam 152 on the first conductive layer 127. The pixel defining layer 134 has an opening.

Next, as shown in FIG. 10, a display function layer 130 is formed on a side of the driver circuit layer 120 away from the substrate 110. For example, a light emitting layer 132 in the opening of the pixel defining layer 134 and a second electrode layer 133 covering the pixel defining layer 134 and in contact with the light emitting layer 132 can be formed.

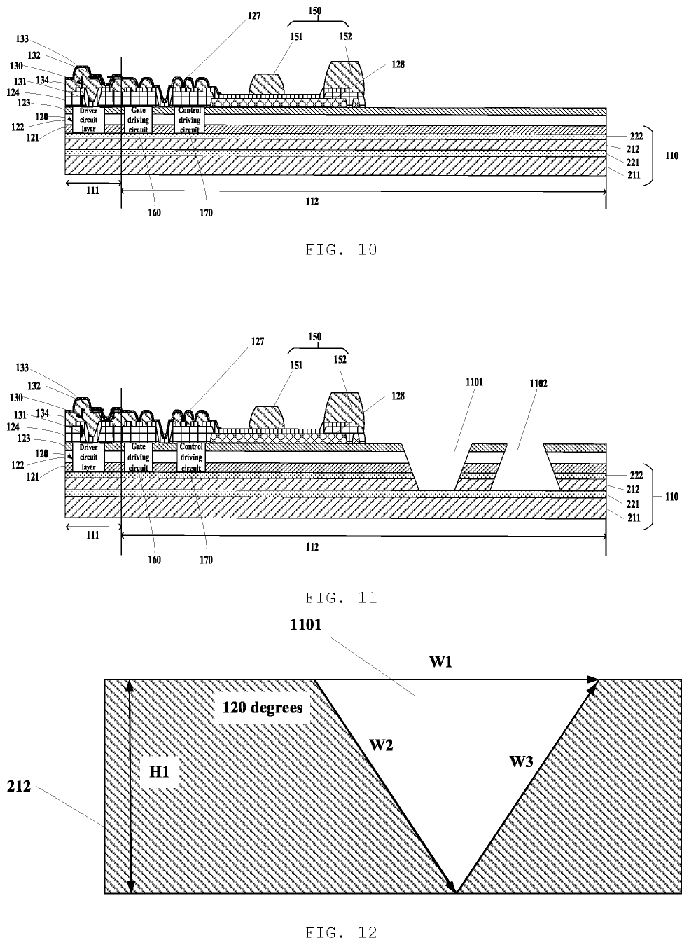

Next, as shown in FIG. 11, the non-display area 112 of the substrate 110 is etched to form a first groove 1101 in the non-display area 112, the first groove 1101 being on a side of the dam 150 away from the display area 111.

For example, the step of etching the non-display area of the substrate comprises: etching the second buffer layer 222 and the second substrate 212 to form the first groove 1101 exposing a portion of the first buffer layer 221. If the first insulating layer 121, the second insulating layer 122 and the interlayer dielectric layer 123 are also formed on the non-display area 112 of the substrate 110 in the processes of forming the first insulating layer 121, the second insulating layer 122 and the interlayer dielectric layer 123, the etching process for forming the first groove also needs to etch a portion of the first insulating layer 121, the second insulating layer 122 and the interlayer dielectric layer 123 on the non-display area 112.

In some embodiments, as shown in FIG. 10, the step of etching the non-display area of the substrate further comprises: etching the second buffer layer 222 and the second substrate 212 to form a second groove 1102 exposing another portion of the first buffer layer 221, the second groove 1102 being on a side of the first groove 1101 away from the dam. Similarly, if the first insulating layer 121, the second insulating layer 122 and the interlayer dielectric layer 123 are also formed on the non-display area 112 of the substrate 110 in the processes of forming the first insulating layer 121, the second insulating layer 122 and the interlayer dielectric layer 123, the etching process for forming the second groove also needs to etch another portion of the first insulating layer 121, the second insulating layer 122 and the interlayer dielectric layer 123 on the non-display area 112.

In some embodiments, the etching process for forming the first groove and the second groove may be dry etching or laser etching (or referred to as laser ablation). For example, a groove with an obtuse angle or an acute angle can be formed by controlling different flow rates of an etching gas. For another example, a groove structure can be formed on a flexible substrate by a laser etching process, and then an inorganic film layer can be deposited thereon.

Next, as shown in FIG. 5, an encapsulation layer 140 is formed on a side of the display function layer 130 away from the driver circuit layer 120. For example, the encapsulation layer 140 comprises an inorganic encapsulation layer. The inorganic encapsulation layer may comprise a first inorganic encapsulation layer 141 on a side of the display function layer 130 away from the driver circuit layer 120 and a second inorganic encapsulation layer 142 on a side of the first inorganic encapsulation layer 141 away from the display function layer 130. For example, the first inorganic encapsulation layer 141 and the second inorganic encapsulation layer 142 can be formed by a chemical vapor deposition process. The inorganic encapsulation layer extends to the non-display area and covers the dam 150, and a portion of the inorganic encapsulation layer is in the first groove 1101.

In some embodiments, the portion of the inorganic encapsulation layer in the first groove 1101 is in contact with the portion of the first buffer layer 221 in the forming of the encapsulation layer. In other embodiments, another portion of the inorganic encapsulation layer is in the second groove 1102 and is in contact with the another portion of the first buffer layer 221 in the forming of the encapsulation layer.

In some embodiments, as shown in FIG. 5, in the process of forming the encapsulation layer, an organic encapsulation layer 143 located between the first inorganic encapsulation layer 141 and the second inorganic encapsulation layer 142 can also be formed. For example, the first inorganic encapsulation layer 141 can be formed first, then the organic encapsulation layer 143 can be formed on the first inorganic encapsulation layer 141, and the second inorganic encapsulation layer 142 can be formed on the organic encapsulation layer 143.

Heretofore, a manufacturing method of a display panel according to some embodiments of the present disclosure is provided. In the manufacturing method, the first groove and the second groove are formed in the non-display area of the substrate, and a portion of the inorganic encapsulation layer extends into the first groove and the second groove. In the manufacturing method, the first groove can improve the water and oxygen barrier property of the display panel for a display device having a narrow border, and the second groove can play the role of blocking cracks.

FIG. 12 is a schematic cross-sectional view showing a first groove of a display panel according to an embodiment of the present disclosure.

For example, as shown in FIG. 12, a width W1 of an opening of the first groove 1101 is 10 microns, the angle α is 120°, and a thickness H1 of the second substrate 212 may be 10 microns. Thus, the cross-section of the first groove 1101 may be approximated to an equilateral triangle, and widths W2 and W3 of two sidewalls of the first groove may be 10 microns, respectively. Since the inorganic encapsulation layer covers the two sidewalls, the extension length of the portion of the inorganic encapsulation layer in the first groove is 20 microns. This can make the extension length of the inorganic encapsulation layer 10 microns longer than that in the related art. Currently, this is only an effect of one first groove, and as the number of the first grooves increases, the extension length of the inorganic encapsulation layer can further increase.

Heretofore, various embodiments of the present disclosure have been described in detail. In order to avoid obscuring the concepts of the present disclosure, some details known in the art are not described. Based on the above description, those skilled in the art can understand how to implement the technical solutions disclosed herein.

Although some specific embodiments of the present disclosure have been described in detail by way of example, those skilled in the art should understand that the above examples are only for the purpose of illustration and are not intended to limit the scope of the present disclosure. It should be understood by those skilled in the art that modifications to the above-described embodiments or equivalently substitution of part of the technical features may be made without departing from the scope and spirit of the present disclosure. The scope of the present disclosure is defined by the appended claims.

1. A display panel, comprising:
a substrate comprising a display area and a non-display area on at least one side of the display area, wherein the substrate has a first groove in the non-display area;
a driver circuit layer on a side of the display area of the substrate;
a display function layer on a side of the driver circuit layer away from the substrate;
an encapsulation layer on a side of the display function layer away from the driver circuit layer, wherein the encapsulation layer comprises an inorganic encapsulation layer, the inorganic encapsulation layer extending to the non-display area, and a portion of the inorganic encapsulation layer being in the first groove; and
a dam on the non-display area of the substrate, wherein an orthographic projection of the dam on the substrate is between the first groove and the display area, and the dam is covered by the inorganic encapsulation layer.

2. The display panel according to claim 1, wherein an angle formed between a sidewall of the first groove and an upper surface of the substrate is greater than 90 degrees.

3. The display panel according to claim 2, wherein a width of an opening of the first groove is greater than a width of a bottom of the first groove.

4. The display panel according to claim 1, wherein the substrate comprises: a first substrate, a first buffer layer on the first substrate, a second substrate on a side of the first buffer layer away from the first substrate, and a second buffer layer on a side of the second substrate away from the first buffer layer, wherein the first groove is at least disposed on the second substrate.

5. The display panel according to claim 4, wherein a bottom of the first groove exposes a portion of the first buffer layer, and the portion of the inorganic encapsulation layer in the first groove is in contact with the portion of the first buffer layer.

6. The display panel according to claim 4, wherein a width of an opening of the first groove in a direction perpendicular to an extension direction of the first groove is 10 microns to 100 microns.

7. The display panel according to claim 1, wherein the substrate comprises a plurality of first grooves, wherein the plurality of first grooves are substantially arranged along an extension direction of an edge of the substrate, and any two of the plurality of first grooves are not connected with each other.

8. The display panel according to claim 1, wherein the first groove extends substantially along an extension direction of an edge of the substrate.

9. The display panel according to claim 1, wherein the dam comprises a first dam and a second dam on a side of the first dam away from the display area, wherein an orthographic projection of the second dam on the substrate is between an orthographic projection of the first dam on the substrate and the first groove.

10. The display panel according to claim 1, wherein:
the inorganic encapsulation layer comprises a first inorganic encapsulation layer on a side of the display function layer away from the driver circuit layer and a second inorganic encapsulation layer on a side of the first inorganic encapsulation layer away from the display function layer; and
the encapsulation layer further comprises an organic encapsulation layer between the first inorganic encapsulation layer and the second inorganic encapsulation layer.

11. The display panel according to claim 1, wherein:
the non-display area comprises: a first non-display area, a second non-display area, a third non-display area and a fourth non-display area all around the display area, wherein the first non-display area is adjacent to the second non-display area, the third non-display area is opposite to the first non-display area, and the fourth non-display area is opposite to the second non-display area;
a first corner area is arranged between the first non-display area and the second non-display area, a second corner area is arranged between the second non-display area and the third non-display area, a third corner area is arranged between the third non-display area and the fourth non-display area, and a fourth corner area is arranged between the first non-display area and the fourth non-display area; and
the first groove is in at least one of the first corner area, the second corner area, the third corner area or the fourth corner area, or at least one of the first non-display area, the second non-display area, the third non-display area or the fourth non-display area.

12. The display panel according to claim 11, wherein the display area comprises a stretchable display area, the first corner area, the second corner area, the third corner area and the fourth corner area being arranged on a side of the stretchable display area.

13. The display panel according to claim 1, wherein the substrate further has a second groove on a side of the first groove away from the dam, wherein another portion of the inorganic encapsulation layer is in the second groove,
wherein an angle formed between a sidewall of the second groove and an upper surface of the substrate is less than 90 degrees, or an angle formed between the sidewall of the second groove and a bottom of the second groove is less than 90 degrees.

14. (canceled)

15. The display panel according to claim 13, wherein a width of an opening of the second groove is less than a width of a bottom of the second groove.

16. The display panel according to claim 13, wherein the another portion of the inorganic encapsulation layer in the second groove forms a slit at a bottom corner of the second groove.

17. The display panel according to claim 13, wherein the second groove extends substantially along an extension direction of an edge of the substrate.

18. The display panel according to claim 13, wherein a depth of the second groove is approximately equal to a depth of the first groove.

19. A display device, comprising: the display panel according to claim 1.

20. A manufacturing method of a display panel, comprising:
providing a substrate comprising a display area and a non-display area on at least one side of the display area;
forming a driver circuit layer on a side of the display area of the substrate;
forming a dam on the non-display area of the substrate;
forming a display function layer on a side of the driver circuit layer away from the substrate;
etching the non-display area of the substrate to form a first groove in the non-display area, the first groove being on a side of the dam away from the display area; and
forming an encapsulation layer on a side of the display function layer away from the driver circuit layer, wherein the encapsulation layer comprises an inorganic encapsulation layer, the inorganic encapsulation layer extending to the non-display area and covering the dam, and a portion of the inorganic encapsulation layer being in the first groove.

21. The manufacturing method according to claim 20, wherein:
the providing of the substrate comprises:
providing a first substrate;
forming a first buffer layer on the first substrate;
forming a second substrate on a side of the first buffer layer away from the first substrate; and
forming a second buffer layer on a side of the second substrate away from the first buffer layer; and
the etching of the non-display area of the substrate comprises: etching the second buffer layer and the second substrate to form the first groove exposing a portion of the first buffer layer;
wherein the portion of the inorganic encapsulation layer in the first groove is in contact with the portion of the first buffer layer in the forming of the encapsulation layer.

22. (canceled)
